(19) United States
(12) Patent Application Publication
(10) Pub. No.: US 2001/0040971 A1
(43) Pub. Date: Nov. 15, 2001

(54) TELEVISION RECEIVER WITH MEMORY CONTAINING AUDIO EQUALIZATION DATA FOR SPECIIFIC RECEIVER HOUSING

(76) Inventors: ULRICH ADRION, TROSSINGEN (DE); PASCAL CHEVALIER, LA CELLE SAINT CLOUD (FR); DAN KING, VILLINGEN-SCHWENNINGEN (DE)

Correspondence Address: JOSEPH S TRIPOLI, THOMSON MULTIMEDIA LICENSING INC, P O BOX 5312, 2 INDEPENDENCE WAY, PRINCETON, NJ, 085435312

(21) Appl. No.: 09/340,899

(22) Filed: Jun. 28, 1999

(30) Foreign Application Priority Data
Jun. 30, 1998 (DE) 198 29 009.8

(51) Int. Cl. H03G 5/00; H04R 29/00

(52) U.S. Cl. 381/98; 381/103; 381/59

(57) ABSTRACT

It is known that different types of housing have different natural resonances. In the case of loudspeaker boxes measures are taken to ensure that an appropriate frequency range is used so that the loudspeakers produce a good sound impression in conjunction with the boxes. These measures are not taken in the case of consumer electronics devices such as a television set or an inexpensive audio system.

The invention is based on the object of providing a method and/or a circuit for improving the sound impression in an consumer electronics device.

The method according to the invention for improving the sound impression in an consumer electronics device having a housing, a control unit, an audio input signal, an audio output signal and a memory is distinguished by the fact that housing-specific sound-characteristic data are stored in the memory, and in that the control unit changes the audio input signal with reference to the stored data in such a way that the audio output signal changes.

### FIELD OF THE INVENTION

The invention is based on a method and a circuit for improving the sound impression in a consumer electronics device.

### BACKGROUND OF THE INVENTION

It is known that different types of housings have a different natural resonance. In the case of loudspeaker boxes, measures are taken to ensure that an appropriate frequency range is used so that the loudspeakers produce a good sound impression in conjunction with the boxes. Less importance is attached to such measures in the case of consumer electronics devices such as a television set or an inexpensive audio system. As a result, a specific type of frame is used in different designs of television housings so that a different sound impression is obtained in each case. In the case of inexpensive audio systems, for reasons of cost low-priced boxes are used which usually do not have a good sound impression.

### SUMMARY OF THE INVENTION

The invention is based on the object of providing a method and/or a circuit for improving the sound impression in a consumer electronics device. This object is achieved by means of the features specified in claim 1. Advantageous improvements of the invention are specified in the subclaims.

The method according to the invention for improving the sound impression in a consumer electronics device having a housing, a control unit, an audio input signal, an audio output signal and a memory is distinguished by the fact that housing-specific sound-characteristics characteristic data are stored in the memory and that the control unit changes the audio input signal with reference to the stored data in such a way that the audio output signal is changed. This has the advantage that an improvement in the sound impression is acquired in a simple way. The housing data relating to each housing are stored in the memory during production so that when the device is activated by the user, the user is provided with the sound impression which is considered the optimum one in a normal situation.

In addition, the method is distinguished by the fact that the control unit is formed from a microprocessor and/or an integrated circuit for audio signals.

As a rule, the microprocessor operates with integrated circuits for audio signals. However, it is also possible that a microprocessor already contains this integrated circuit. In this way, a compact design is made possible. If the microprocessor does not contain this integrated circuit, a better degree of compatibility is provided since possible other integrated circuits, which have been improved at a later date, for audio signals and/or more powerful microprocessors can be used.

The method is also distinguished by the fact that the control unit is connected to an equalizer and/or that an equalizer is implemented.

The control unit may contain an equalizer or be connected to one. The equalizer is preferably implemented in the form of software, i.e. the user can modify the individual areas of the frequency response on the screen by remote control. This procedure enables him to modify the sound-characteristic data to values which are the most pleasant for him. In the simplest case, this equalizer could be a dual band equalizer. There are no upper limits on the division of the equalizer for the band widths, five bands being preferably used.

Furthermore, the method is distinguished by the fact that the housing-specific sound-characteristic data are stored in the memory, for example in an integrated circuit, and/or that during the production process, the data are stored in the memory by means of the control unit during the production process, and/or that the data are already stored in the memory before production.

The housing-specific sound-characteristic data can, as described above, be fed into the memory in various ways, it is important that the data are present in the memory before the user activates the television, or otherwise he would have to set the sound-characteristic data of his device manually. This could be carried out by means of the equalizer. This means that a leaflet containing the optimum equalizer setting is enclosed with each type of device so that the user can set the device in this way.

Moreover, the method is distinguished by the fact that the housing-specific sound-characteristic data are arranged in the audio signal path by means of a circuit.

It is also possible for a circuit in the form of hardware, to be positioned in the audio signal path so that the housing-specific sound-characteristic data would influence the signal path in this way.

A circuit according to the invention for improving the sound impression in a consumer electronics device having a housing, a control unit, an audio input signal, an audio output signal and a memory is distinguished by the fact that the memory contains housing-specific sound-characteristic data, and that the control unit changes the audio input signal with reference to the stored data in such a way that the signal profile of the audio output signal can be changed.

In the case of audio systems or in a television set in which the loudspeakers are arranged externally, the housing data which are to be used are the data of the boxes since the latter adversely affect the sound impression. If the appliance is an audio system, the equalizer is actuated, for example, not by means of software using the screen as described previously but rather controlled by means of controllers. This also constitutes an alternative solution for a television set, and the software solution for the equalizer certainly gives a more pleasant impression. According to the principles of the invention it is also possible for any loudspeaker box to be equipped with such housing-specific sound impressions so that the user of an audio system or of a television set etc. can set the data using the setting facilities of the respective device. This would be a simple method of ensuring that an optimum sound impression is acquired from a housing.

### BRIEF DESCRIPTION OF THE DRAWINGS

The invention is explained below with reference to the figures. Identical reference symbols indicate an identical method of operation. In said drawing:

FIG. 1 shows a block diagram of the method and/or circuit according to the invention;

FIGS. 2a-d show signal profiles of the method and/or circuit according to the invention and

FIGS. 3 and 4 show further exemplary embodiments of the method and/or circuit according to the invention.

### DETAILED DESCRIPTION OF PREFERED EMBODIMENTS

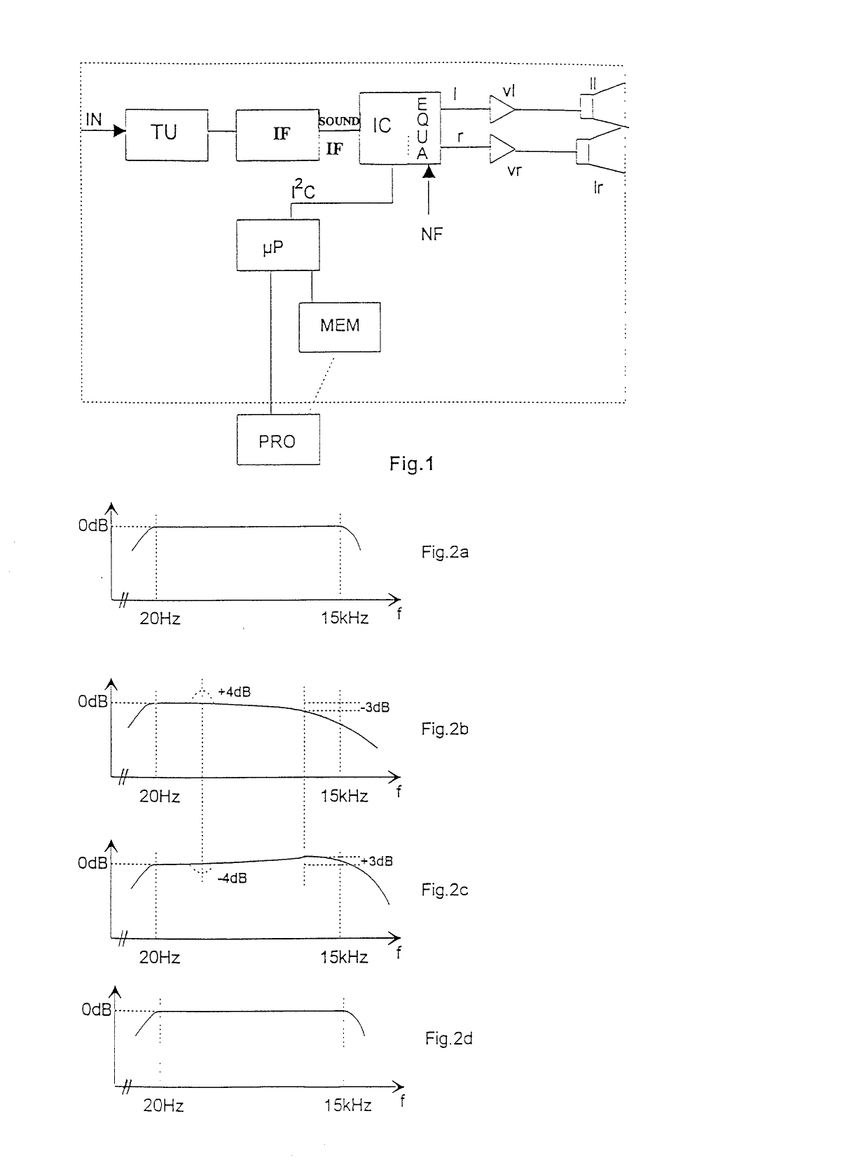

FIG. 1 shows a block diagram of the method and/or circuit according to the invention for use, for example, in a television set. It contains an antenna input signal IN which is fed to the IF circuit IF via the tuner TU. The audio IF element is then passed to the integrated circuit IC. The integrated circuit IC receives a control signal from the microprocessor μP via the I²C bus and further audio signals, for example from the Scart sockets via the AF input. The integrated circuit IC is connected to an equalizer EQUA or contains the equalizer function as indicated here by broken lines. The audio signal l, r is then fed from the integrated circuit to the corresponding loudspeaker ll, lr via appropriate amplifier circuits vl, vr. The microprocessor receives the housing-specific sound-characteristic data from the unit PRO during production. These data which are referred to below as data are passed on to the memory MEM by the microprocessor. As an alternative to this, it is also possible for the data to be fed directly into the memory MEM by the unit PRO during production. As a further alternative, the data are already stored in the memory MEM before the device is produced and are thus already present during production. If the equalizer EQUA is not contained in the integrated circuit, it could be actuated by it. However, it is also possible for the microprocessor uP to carry out an actuation operation by means of the I²C bus.

The method of operation of the circuit will be explained with the aid of FIG. 2. An ideal profile of the acoustic signal is displayed in FIG. 2a. The transmitted frequency range extends between 20 Hz and 15 kHz. 0 dB is given as a reference value which should, as a rule, remain constant. This 0 dB reference value could be given, for example, a power of 1.5 or 10 Watts, it serves merely as a reference value. FIG. 2b shows how a glitch of about 3 dB appears at the upper end of the frequency range as a result of the shape of the housing. This means that the user perceives a duller sound. These losses of quality are brought about for example by the fact that loudspeakers without grilles are used in newer devices and are let into the plastic frame directly. As a result, the acoustic signal is damped at relatively high frequencies. FIG. 2c then shows how a boost of about 3 dB is carried out by electrical means precisely at the point at which the drop owing to the housing takes place. FIG. 2d then shows that virtually an optimum profile is acquired. This means that the loudspeakers ll, lr can provide the user with an improved sound impression. The manufacturer obtains the housing data by performing measurements with the housing in order to determine where the glitches in the frequency response are situated. Thus, it is therefore also conceivable for there to be a boost at a frequency of 4000 kHz, shown here in FIG. 2b with a value of 4 dB by broken lines. Furthermore, a plurality of glitches or signal boosts are possible in a frequency range. These data are then acquired by measurement and then fed into the memory which effects a signal boost by electrical means so that this boost together with a drop as a result of structural features of the housing produce an improved sound impression.

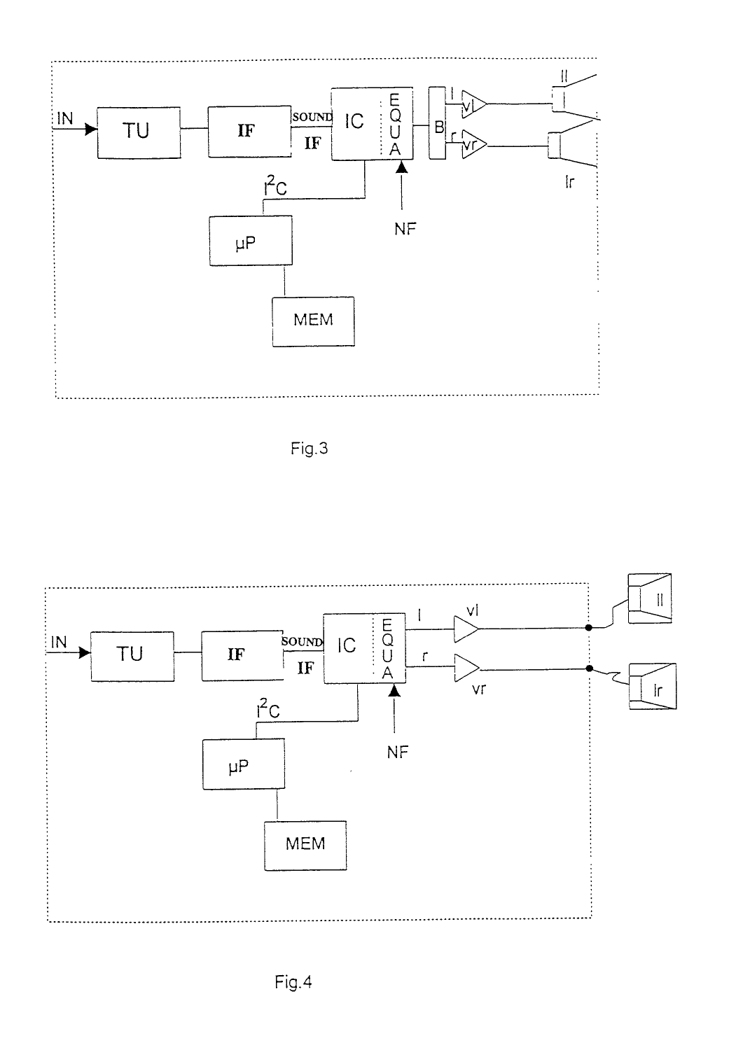

FIG. 3 shows a development of the block diagram diagram from FIG. 1. An assembly B, which also makes it possible to improve the sound impression, has now been integrated in the audio signal path. The assembly is composed, for example, of inductors, resistors and capacitors which change the frequency response in accordance with the housing data. This means that the assembly changes the electrical signal in such a way that, depending on the housing data, the signal is boosted at appropriate points in order to bring about compensation, as already described with reference to FIG. 2.

FIG. 4 shows a solution which can be used in a television set in which the loudspeakers ll, lr are arranged externally. The housing data to be used are the data of the boxes because they adversely affect the sound impression. As described previously, the equalizer can also be actuated by software, via the screen.

What is claimed, is:

1. Method for improving the sound impression in a consumer electronics device with a housing, a control unit (μp, ic), an audio input signal, an audio output signal and a memory (MEM), characterized in that housing-specific sound-characteristic data are stored in the memory (MEM), and in that the control unit (μp, ic) changes the audio input signal with reference to the stored data in such a way that the audio input signal is corrected.

2. Method according to claim 1, characterized in that the control unit is formed from a microprocessor and/or an integrated circuit for audio signals.

3. Method according to claim 1, characterized in that the control unit is connected to an equalizer and/or in that an equalizer is implemented.

4. Method according to claim 1, characterized in that the housing-specific sound-characteristic data are stored in the memory during the production process and/or in that the data are stored in the memory by means of the control unit during the production process and/or in that the data are already stored in the memory before production.

5. Method according to claim 1, characterized in that the housing-specific sound-characteristic data are arranged in the audio signal path by means of a circuit.

6. Circuit for improving the sound impression in a consumer electronics device with a housing, a control unit, an audio input signal, an audio output signal and a memory, characterized in that the memory (MEM) contains housing-specific sound-characteristic data, and in that the control unit changes the audio input signal with reference to the stored data in such a way that the signal profile of the audio output signal is corrected.
